(19) United States
(12) Patent Application Publication
(10) Pub. No.: US 2024/0384069 A1
(43) Pub. Date: Nov. 21, 2024

(54) COATED GLASS BUBBLES, COMPOSITES THEREFROM, AND METHODS OF MAKING THE SAME

(71) Applicant: 3M INNOVATIVE PROPERTIES COMPANY, St. Paul, MN (US)

(72) Inventors: Adam D. Miller, Vadnais Heights, MN (US); Jean A. Tangeman, Minneapolis, MN (US); Yong K. Wu, Woodbury, MN (US); Eisuke Fujiwara, Kanagawa (JP); Takujiro Yamabe, Kanagawa (JP); Taiki Ihara, Tokyo (JP)

(21) Appl. No.: 18/692,359

(22) PCT Filed: Sep. 19, 2022
(86) PCT No.: PCT/US2022/076647

§ 371 Date: Mar. 15, 2024

Related U.S. Application Data
(60) Provisional application No. 63/261,368, filed on Sep. 20, 2021.
(60) Provisional application No. 63/375,707, filed on Sep. 15, 2022.

(51) Int. Cl. C08K 9/02; C03C 17/245; C03C 17/25; C08K 3/36; C08K 7/28; C23C 16/40; C23C 16/44; C23C 16/56; H05K 1/03

(52) U.S. Cl. CPC C08K 9/02; C03C 17/245; C03C 17/25; C08K 3/36; C08K 7/28; C23C 16/402; C23C 16/4417; C23C 16/56; H05K 1/0373; C03C 2217/213; C03C 2218/111; C03C 2218/1525; C03C 2218/32; C08K 2201/003

(57) ABSTRACT

Silica coated glass bubbles comprising a glass bubble and a silica coating in direct contact with the outer surface of the bubble, wherein the silica coating is substantially free of silanol groups. A composite comprising a polymer and a plurality of the silica coated glass bubbles dispersed therein. Articles comprising the composite. Methods for making the silica coated glass bubbles.

### FIELD OF INVENTION

The present disclosure broadly relates to coated glass bubbles, composites containing the coated glass bubbles, and methods of their manufacture.

### BACKGROUND

Glass bubbles having an average diameter of less than about 500 micrometers (μm), also commonly known as “glass microbubbles”, “hollow glass microspheres”, or “hollow glass beads”, are used in a variety of applications ranging from explosive materials to advances in the electrification of automobiles. The glass bubbles are often used as fillers to lower the density (i.e. light weighting), lower the coefficient of thermal expansion, and/or lower the thermal conductivity of other materials. Glass bubbles can also be added to materials to lower the dielectric constant (Dₖ), making them suitable for producing lightweight composites with desired electrical properties (e.g., printed circuit boards and radomes).

Despite the advantages noted above, glass bubbles are not a low loss material and, in some cases, can increase the dielectric loss of a composite to which they have been added. With the telecommunications industry shifting to ever higher frequencies, there is an increasing demand for materials that exhibit both a low dielectric constant and a low dielectric loss.

### SUMMARY

The present disclosure provides coated glass bubbles, more particularly silica coated glass bubbles comprised of soda-lime borosilicate glass. As noted above, the hollow glass bubbles typically are not a low dielectric loss material. However, glass bubbles made from soda-lime borosilicate glass have an additional tendency to absorb water, which can further increase the dielectric loss and, in some instances, also lead to undesirable heating resulting from the energy loss. Moreover, glass bubbles comprising soda-lime borosilicate glass can undergo alkali (e.g., sodium) leaching into the composite material. In applications where the glass bubbles are incorporated into composites used to make printed circuit boards, the leaching of sodium can accumulate on the solder of the printed circuit boards and lead to crosstalk and potential shorting of the circuit boards.

The silica coating described herein reduces water adsorption and/or reduces alkali leaching of the soda-lime borosilicate glass bubbles, thus making them ideally suited for applications in the telecommunications and electronics industries. Moreover, the silica coating provides an additional layer of durability to the glass bubbles which also benefits a variety of other applications. including paints, coatings, and high temperature applications for metal matrices.

In one embodiment, the present disclosure provides a particle comprising: a glass bubble having an outer surface; and a silica coating in direct contact with the outer surface, wherein the silica coating is substantially free of silanol groups.

In another embodiment, the present disclosure provides a method of making a plurality of the particles, the method comprising: providing a plurality of the glass bubbles; depositing a silica coating onto the surface of the glass bubbles by chemical vapor deposition (CVD) with a silica CVD precursor; and calcining the coated glass bubbles.

In yet a further embodiment, the present disclosure provides a second method of making a plurality of the particles, the method comprising: providing a plurality of the glass bubbles; depositing a silica coating onto the surface of the glass bubbles by solution coating, the silica coating resulting from the hydrolysis of a silica precursor in alcohol in the presence of an ammonia catalyst; separating the silica coated glass bubbles from the solution; and calcining the silica coated glass bubbles.

In yet another embodiment, the present disclosure provides a third method of making a plurality of the particles, the method comprising: providing a plurality of the glass bubbles; depositing a silica coating onto the surface of the glass bubbles by solution coating, the silica coating resulting from the hydrolysis of a silica precursor in alcohol in the presence of a basic amino acid catalyst (e.g., L(+)-arginine, L(+)-lysine, and/or L-histidine); separating the silica coated glass bubbles from the solution; and calcining the silica coated glass bubbles.

In another embodiment, the present disclosure provides a composite comprising a polymer and a plurality of the particles dispersed within the polymer.

In yet a further embodiment, the present disclosure provides an article comprising the composite.

As used herein:

The term “comprises” and variations thereof do not have a limiting meaning where these terms appear in the description and claims. Such terms will be understood to imply the inclusion of a stated step or element or group of steps or elements but not the exclusion of any other step or element or group of steps or elements. By “consisting of” is meant including, and limited to, whatever follows the phrase “consisting of.” Thus, the phrase “consisting of” indicates that the listed elements are required or mandatory, and that no other elements may be present. By “consisting essentially of” is meant including any elements listed after the phrase, and limited to other elements that do not interfere with or contribute to the activity or action specified in the disclosure for the listed elements. Thus, the phrase “consisting essentially of” indicates that the listed elements are required or mandatory, but that other elements are optional and may or may not be present depending upon whether or not they materially affect the activity or action of the listed elements.

In this application, terms such as “a,” “an,” and “the” are not intended to refer to only a singular entity, but include the general class of which a specific example may be used for illustration. The terms “a,” “an,” and “the” are used interchangeably with the phrases “at least one” and “one or more.” The phrases “at least one of” and “comprises at least one of” followed by a list refers to any one of the items in the list and any combination of two or more items in the list.

The term “or” is generally employed in its usual sense including “and/or” unless the content clearly dictates otherwise.

The term “and/or” means one or all of the listed elements or a combination of any two or more of the listed elements.

Also herein, all numbers are assumed to be modified by the term “about” and in certain embodiments, by the term “exactly.” As used herein in connection with a measured quantity, the term “about” refers to that variation in the measured quantity as would be expected by the skilled artisan making the measurement and exercising a level of care commensurate with the objective of the measurement and the precision of the measuring equipment used.

Also herein, the recitations of numerical ranges by endpoints include all numbers subsumed within that range as well as the endpoints (e.g., 1 to 5 includes 1, 1.5, 2, 2.75, 3, 3.80, 4, 5, etc.).

The term “weight percent” or “wt %”, as used herein in reference to a component of a material, refers to the percentage by weight of the component relative to the total weight of the material as a whole.

Reference throughout this specification to “some embodiments” means that a particular feature, configuration, composition, or characteristic described in connection with the embodiment is included in at least one embodiment of the disclosure. Thus, the appearances of such phrases in various places throughout this specification are not necessarily referring to the same embodiment of the disclosure. Furthermore, the particular features, configurations, compositions, or characteristics may be combined in any suitable manner in one or more embodiments.

The words “preferred” and “preferably” refer to embodiments of the disclosure that may afford certain benefits, under certain circumstances; however, other embodiments may also be preferred, under the same or other circumstances. Furthermore, the recitation of one or more preferred embodiments does not imply that other embodiments are not useful, and is not intended to exclude other embodiments from the scope of the disclosure.

The above summary of the present disclosure is not intended to describe each disclosed embodiment or every implementation of the present disclosure. The description that follows more particularly exemplifies illustrative embodiments.

### BRIEF DESCRIPTION OF THE DRAWINGS

FIG. 1 is an exemplary particle of the present disclosure; and

FIG. 2 is an exemplary chemical vapor deposition apparatus for making the particles described herein.

Unless otherwise indicated, all figures and drawings in this document are not to scale and are chosen for the purpose of illustrating different embodiments of the invention. In particular, the dimensions of the various components are depicted in illustrative terms only, and no relationship between the dimensions of the various components should be inferred from the drawings, unless so indicated.

### DETAILED DESCRIPTION

In the following description of illustrative embodiments, reference is made to the accompanying figures of the drawing which form a part hereof, and in which are shown, by way of illustration, specific embodiments. It is to be understood that other embodiments may be utilized and structural changes may be made without departing from the scope of the present invention.

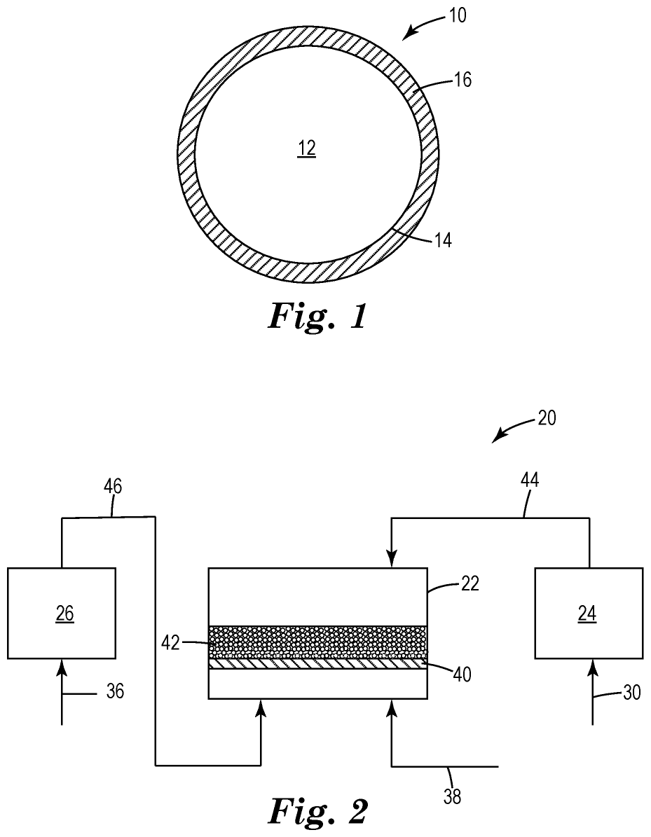

As illustrated in FIG. 1, the coated glass bubbles (or particles) 10 of the present disclosure generally comprise a glass bubble 12 having an outer surface 14, and a silica coating 16 in direct contact with the outer surface 14. The term “direct contact”, as used herein, means the silica coating is in physical contact with the surface of the glass bubbles (i.e., no intermediate coating or layer).

The silica coating is substantially free of silanol groups. Silanol groups are typically formed on the surface of the silica coating during the coating process. However, the silanol groups contribute to the adsorption of water, which can increase the dielectric loss of the coated glass bubbles, as well as composite materials into which they are incorporated. Additionally, the adsorption of water can lead to the degradation of the silica coating over time due to hydrolysis of the Si—O—Si bonds. Therefore, removal of the silanol groups is beneficial to maintaining the structural integrity of the silica coating and to maintaining a reduced dielectric loss. The phrase “substantially free of silanol groups”, as used herein, means that the coated glass bubble has a moisture content of no greater than 500 ppm, 450 ppm, 400 ppm, 350 ppm, 300 ppm, 250 ppm, 200 ppm, 150 ppm, 100 ppm, or 50 ppm moisture content, as determined according to the Moisture Analysis test method in the Examples section. Preferably the moisture content is less than 200 ppm. The moisture content of the coated glass bubbles will decrease as the amount of silanol groups decrease, thus providing a useful measure for silanol content.

The glass bubbles, as used herein, refer to hollow spheres made of glass, each having a substantially single-cell structure (i.e., each bubble is defined by only the outer wall with no additional exterior walls, partial spheres, concentric spheres, or the like present in each individual bubble). The size of the glass bubbles are not particularly limiting and will depend upon the application for which they are intended. In some embodiments, the glass bubbles of the present disclosure each, individually, have a particle diameter ranging from 1 μm to 500 μm, 10 μm to 100 μm, 10 μm to 75 μm, or even 10 μm to 40 μm.

Glass bubbles according to and/or useful for practicing the present disclosure can be made by techniques known in the art (see. e.g., U.S. Pat. Nos. 2,978,340) (Veatch et al.); 3,030,215 (Veatch et al.); 3,129,086 (Veatch et al.); 3,230,064 (Veatch et al.); 3,365,315 (Beck et al.); 4,391,646 (Howell); and 4,767,726 (Marshall); and U. S. Pat. App. Pub. No. 2006/0122049 (Marshall et. al)). Techniques for preparing glass bubbles typically include heating milled frit, commonly referred to as “feed”, which contains a blowing agent (e.g., sulfur or a compound of oxygen and sulfur). The resultant product (that is, “raw product”) obtained from the heating step typically contains a mixture of glass bubbles, broken glass bubbles, and solid glass beads, the solid glass beads generally resulting from milled frit particles that failed to form glass bubbles for whatever reason. The milled frit typically has range of particle sizes that influences the size distribution of the raw product. During heating, the larger particles tend to form glass bubbles that are more fragile than the mean, while the smaller particles tend to increase the density of the glass bubble distribution. When preparing glass bubbles by milling frit and heating the resulting particles, the amount of sulfur in the glass particles (i.e., feed) and the amount and length of heating to which the particles are exposed (e.g., the rate at which particles are fed through a flame) can typically be adjusted to vary the density of the glass bubbles. Lower amounts of sulfur in the feed and faster heating rates lead to higher density bubbles as described in U.S. Pat. Nos. 4,391,646 (Howell) and 4,767,726 (Marshall). Furthermore, milling the frit to smaller sizes can lead to smaller, higher density glass bubbles.

Although the frit and/or the feed may have any composition that is capable of forming a glass, in some embodiments the frit comprises from 50 to 90 wt % SiO₂, from 2 to 20 wt % alkali metal oxides (for example, Na₂O or K₂O), from 1 to 30 wt % B₂O₃, from 0.005-0.5 wt % sulfur (for example, as elemental sulfur, sulfate or sulfite), from 0 to 25 wt % divalent metal oxides (for example, CaO, MgO, BaO, SrO, ZnO, or PbO), from 0 to 10 wt % tetravalent metal oxides other than SiO₂ (for example, TiO₂, MnO₂, or ZrO₂), from 0 to 20 wt % trivalent metal oxides (for example, Al₂O₃, Fe₂O₃, or Sb₂O₃), from 0 to 10 wt % oxides of pentavalent atoms (for example, P₂O₅ or V₂O₅), and from 0 to 5 wt % fluorine (as fluoride) which may act as a fluxing agent to facilitate melting of the glass composition. Additional ingredients are useful in frit compositions and can be included in the frit, for example, to contribute particular properties or characteristics (for example, hardness or color) to the resultant glass bubbles.

Suitable glass bubbles may also be obtained commercially from, for example, 3M Company (Saint Paul. Minnesota) under the designation 3M™ Glass Bubbles K, S, iM, XLD, Floated and HGS Series, including Glass Bubbles iM16K, Glass Bubbles S60, and Glass Bubbles K42HS. Additional suitable glass bubbles include 3M™ Glass Bubbles S4630.

In some embodiments, the glass bubbles comprise a soda-lime borosilicate glass.

In some embodiments, the glass bubbles comprise 50 to 90 wt % silica (SiO₂); 2 to 20 wt % alkali metal oxides (R₂O); and 1 to 30 wt % boron oxide (B₂O₃). In the same, or different embodiments, the glass bubble comprises no greater than 25 wt % divalent metal oxide (RO), more particularly calcium oxide (CaO). In the same, or different embodiments, the glass bubble further comprises no greater than 10 wt % phosphorus oxide (P₂O₅). As used herein, “R” refers to a metal having the valence indicated, R₂O an alkali metal oxide and RO being a divalent metal oxide, preferably an alkaline earth metal oxide.

The particles of the present disclosure have a silica coating in direct contact with the outer surface of the glass bubbles. The silica is typically amorphous and the coating substantially free of silanol groups, as mentioned above. The silica coating typically covers at least 90%, at least 95%, or 100% of the outer surface of the glass bubble. Preferably, the silica coating encapsulates the glass bubble (i.e., covers 100% of the outer surface). In some embodiments, the silica coating is continuous. In less favorable embodiments, the silica coating is discontinuous (i.e., coated regions separated by uncoated regions on the surface of the bubble).

It is preferable that the thickness of the silica coatings be as thin as practically possible. To some extent this will depend upon the application. Coatings that are too thin may lack durability. Coatings that are too thick may result in unnecessarily high density and dielectric constants. Preferably, the coating thickness is less than the wall thickness of the glass bubbles, which is typically about 500 nm. In some embodiments, the thickness of the silica coatings range from 50 nm to 250 m, or even 50 nm to 150 nm. Silica coatings typically have less than 5%, less than 2%, or even less than 1% porosity.

The silica coating can be applied to the glass bubbles, for example, by a vapor phase method or a solution phase method.

In one embodiment, the coating can be applied to the glass bubbles by a chemical vapor deposition (CVD) process, which generally includes providing a plurality of the glass bubbles, depositing a silica coating onto the surface of the glass bubbles by chemical vapor deposition with a silica CVD precursor, and calcining the coated glass bubbles to remove water and silanol groups.

More specifically, uncoated glass bubbles are placed in a reaction chamber (i.e. reactor) and optionally heated to an appropriate temperature, typically no greater than 300° C. to achieve the desired coating deposition. The glass bubbles are preferably agitated during the coating process in order to insure the formation of a substantially continuous coating of silica on the surfaces of the bubbles. Exemplary agitation methods include shaking, vibrating, or rotating the reactor, stirring the glass bubbles, or suspending the glass bubbles in a fluidized bed. In some embodiments, two or more methods of agitation may be employed simultaneously.

CVD precursor materials (e.g., tetrachlorosilane, tetrabromosilane, or combinations thereof) and water are typically introduced into the reactor in the vapor phase using two separate feed lines. Within the reactor, a vapor phase hydrolysis reaction is used to deposit the silica coating on the surfaces of the glass bubbles thereby encapsulating them. An illustrative hydrolysis reaction is provided below:

SiCl₄+2H₂O→SiO₂+4HCl

One technique for getting the precursor materials into the vapor phase and adding them to the reactor is to bubble a stream of gas, preferably inert, referred to herein as a carrier gas, through a solution or neat liquid of the precursor material(s) and into the reactor. Illustrative examples of inert gases which may be used herein include argon and nitrogen. Oxygen and/or dry air may also be used. An advantage of this technique is that the carrier gas/precursor streams may be used to fluidize the glass bubbles in the reactor, thereby facilitating the desired encapsulation process. In addition, such a technique provides means for readily controlling the rate of introduction of the precursor materials into the reactor.

An exemplary apparatus 20 for the CVD process is illustrated in FIG. 2. The apparatus comprises a reactor 22, a CVD precursor chamber 24, and a water chamber 26. In some embodiments, a frit 40 is used as a platform to support a bed of the glass bubbles 42. A stream of water vapor 46 is introduced into the bottom of reactor 22 by bubbling a stream of nitrogen carrier gas 36 through the water stored within chamber 26. In addition to providing the water vapor for reaction, this stream of nitrogen is used to fluidized the glass bubbles 42. Alternatively, or in addition, a mechanical stirrer is used to agitate the glass bubbles within the reactor 22. At the same time, CVD precursor vapor 44 is introduced into the reactor in a stream of nitrogen carrier gas 30 by bubbling the nitrogen carrier gas 30 through a neat liquid CVD precursor (e.g., tetrachlorosilane, tetrabromosilane, or combinations thereof) stored within the chamber 24. In some embodiments, an additional stream of nitrogen gas 38 is introduced into the reactor 22 below the frit 40. The water vapor and CVD precursor vapor react within the reaction chamber to deposit a silica coating on the surfaces of the glass bubbles.

Precursor flow rates are adjusted to provide an adequate deposition rate and to provide a silica coating of desired quality and character. Flow rates are adjusted such that the ratios of precursor materials (e.g., CVD precursor and water) present in the reactor promote oxide deposition at the surface of the glass bubbles with minimal formation of discrete, i.e. free floating, oxide particles, elsewhere in the reactor.

Optimum flow rates for a particular application typically depend in part upon the temperature within the reactor, the temperature of the precursor streams, the degree of agitation within the reactor, and the particular precursors being used, but useful flow rates may be readily determined with trial and error. In preferred embodiments, the flow rate of carrier gas used to transport the precursor materials to the reactor is sufficient to agitate the glass bubbles as desired and also transport optimal quantities of precursor materials to the reactor, thereby conveniently and efficiently meeting those functions.

Preferably, the precursor materials have sufficiently high vapor pressures so that sufficient quantities of precursor material will be transported into the reactor for the hydrolysis reaction and coating process to proceed at a conveniently fast rate. Precursor materials may be heated to increase the vapor pressure of the materials; however, this may necessitate heating of tubing or other means used to transport the precursor materials to the reactor so as to prevent condensation between the source and the reactor. In many instances, precursor materials will be in the form of neat liquids at room temperature. In some embodiments, it may be desirable to utilize several precursors simultaneously in a coating process.

A coating process that operates at a temperature low enough not to undesirably degrade the glass bubbles should be selected. Thus, coating is preferably achieved using a hydrolysis-based atmospheric pressure CVD process at temperatures below about 300° C. more preferably below about 200° C. In some embodiments, the process may be carried out at ambient temperature, although exceedingly low temperatures may result in incomplete reaction of precursor materials and/or lower coating densities, thereby yielding less effective coatings.

Once the silica coating has been deposited on the glass bubbles, the glass bubbles are removed from the reaction chamber and calcined at 650° C. to 750° C. to remove silanol groups and residual water.

In addition to the CVD process, the glass bubbles may also be solution coated using a modified Stöber method. Generally, the method comprises providing a plurality of glass bubbles, depositing a silica coating onto the surface of the glass bubbles by solution coating, separating the silica coated glass bubbles from the solution, and calcining the silica coated glass bubbles to remove silanol groups and residual water.

In one specific embodiment, the glass bubbles are suspended in a solution comprising a silica precursor (e.g., tetramethyl orthosilicate (Si(OMe)₄), tetraethyl orthosilicate (Si(OEt)₄), or combinations thereof) and an alcohol (e.g., methanol or ethanol). Concentrated aqueous ammonia and water are subsequently added and the mixture stirred overnight. The silica precursor is hydrolyzed in the alcohol in the presence of the ammonia catalyst to form the silica coating. The coated glass bubbles are separated from the solution by filtration, washed with alcohol, and dried. The coated glass bubbles are subsequently calcined at temperatures ranging from 650° C. to 750° C.

In another specific embodiment, the glass bubbles, alcohol (e.g., methanol or ethanol), and an aqueous solution of a basic amino acid (e.g., L(+)-arginine, L(+)-lysine, and/or L-histidine) are mixed together at approximately 25° C. for about 30 minutes. A silica precursor (e.g., tetramethyl orthosilicate (Si(OMe)₄), tetraethyl orthosilicate (Si(OEt)₄), or combinations thereof) is then added to the mixture, and the mixture is stirred at elevated temperature (e.g., 60° C.) for about 16 hours. The coated glass bubbles are then filtered and dried at elevated temperature (e.g., 120° C.) for about 2 hours. The coated glass bubbles are subsequently calcined at temperatures ranging from 650° C. to 750° C.

In some preferred embodiments, the glass bubbles may be acid-washed prior to solution coating. Acid-washing may further reduce the potential for sodium leaching from the coated glass bubbles.

The coated glass bubbles of the present disclosure typically exhibit a dielectric constant (Dₖ) no greater than 2. In the same or different embodiments, the coated glass bubbles exhibit a dielectric loss (tan δ) no greater than 0.01, 0.008, 0.007, 0.006, 0.005, 0.004, 0.003, 0.002 or even 0.001. In some embodiments, the coated glass bubbles exhibit a dielectric loss (tan δ) no greater than 0.003.

The silica coating can also reduce the leaching of alkali (e.g., sodium) in some applications, including composites comprising the coated glass bubbles that are used to make printed circuit boards, where the leaching of sodium can lead to crosstalk and potential shorting of the circuit boards. In some embodiments, the coated glass bubbles of the present disclosure leach no greater than 50 ppm, 40 ppm, 30 ppm, 20 ppm, 10 ppm, or even 5 ppm sodium, as determined by the Sodium Leaching Test Method in the Examples section.

Electrical conductivity measurements can also be used to assess alkali leaching. In some embodiments, the coated glass bubbles of the present disclosure have a relative value of electrical conductivity (RVEC), as described in the Examples section, of no more than 0.7, 0.65, 0.60, 0.55, 0.50, 0.45, 0.40, 0.35, 0.30, 0.25, 0.20, 0.15, or 0.10. In some embodiments, the RVEC ranges from 0.01 to 0.7, more particularly 0.01 to 0.40, or even more particularly 0.08 to 0.37. In the same or alternative embodiments, the coated glass bubbles of the present disclosure have a reduction rate of electrical conductivity (RREC), as described in the Examples section, of at least 50, 55, 60, 65, 70, 75, 80, 85, 90, or 95 percent. In some embodiments, the RREC ranges from 50 to 90 percent, more particularly 60 to 95 percent, or even more particularly 63 to 92 percent.

The particles or coated glass bubbles of the present disclosure may be used in a wide variety of applications, for example, in filler applications, modifier applications or containment applications. The coated glass bubbles may be used as filler in composite materials, where they impart properties of cost reduction, weight reduction, improved processing, performance enhancement, improved machinability and/or improved workability. More specifically, they may be used fillers in polymers (including thermoset, thermoplastic, and inorganic geopolymers), inorganic cementitious materials (including material comprising Portland cement, lime cement, alumina-based cements, plaster, phosphate-based cements, magnesia-based cements and other hydraulically settable binders), concrete systems (e.g., precise concrete structures, tilt up concrete panels, columns, or suspended concrete structures), putties (e.g., for void filling and/or patching applications), wood composites (e.g., particleboards, fiberboards, wood/polymer composites, and other composite wood structures), clays, and ceramics. One particularly useful application is in fiber cement building products.

In some embodiments, composites comprise a polymer and a plurality of the particles (i.e. coated glass bubbles) dispersed therein. The polymer may be a thermoplastic or thermoset polymer, and the composite may contain a mixture of polymers. Suitable polymers for the composite may be selected by those skilled in the art, depending at least partially on the desired application.

In some embodiments, the polymer in the composite disclosed herein is a thermoplastic. Exemplary thermoplastics include polyolefins (e.g., polypropylene, polyethylene, and polyolefin copolymers such as ethylene-butene, ethylene-octene, and ethylene vinyl alcohol); fluorinated polyolefins (e.g., polytetrafluoroethylene, copolymers of tetrafluoroethylene and hexafluoropropylene (FEP), perfluoroalkoxy polymer resin (PFA), polychlorotrifluoroethylene (pCTFE), copolymers of ethylene and chlorotrifluoroethylene (pECTFE), and copolymers of ethylene and tetrafluoroethylene (PETFE)); polyimide; polyamide-imide; polyether-imide; polyetherketone resins; polystyrenes; polystyrene copolymers (e.g., high impact polystyrene, acrylonitrile butadiene styrene copolymer (ABS)); polyacry lates; polymethacry lates; polyesters; polyvinylchloride (PVC); liquid crystal polymers (LCP); polyphenylene sulfides (PPS); polysulfones; polyacetals; polycarbonates; polypheny lene oxides (PPO); polyphenyl ether (PPE); and blends of two or more such resins. In some of these embodiments, the thermoplastic is polyethylene (e.g., high density polyethylene (HDPE), low density polyethylene (LDPE), and linear low density polyethylene (LLDPE)). In some embodiments, the thermoplastic is elastomeric. In some embodiments, the polymer in the composite is a thermoplastic comprising at least one of polypropylene or polyethylene (e.g., high density polyethylene (HDPE), low density polyethylene (LDPE), linear low density polyethylene (LLDPE), polypropylene (PP)), and polyolefin copolymers (e.g., copolymers of propylene and ethylene).

In some embodiments, the polymer in the composite disclosed herein is a thermoset. Exemplary thermosets include epoxy, polyester, polyurethane, polyurea, silicone, polysulfide, and phenolic. In some embodiments, the polymer in the composite is a thermoset selected from the group consisting of epoxy, polyurethane, silicone, and polyester. In some embodiments, the thermoset is elastomeric.

In some embodiments, the polymer in the composite disclosed herein is elastomeric. Exemplary useful elastomeric polymers include polybutadiene, polyisobutylene, ethylene-propylene copolymers, ethylene-propy lene-diene terpolymers, sulfonated ethylene-propylene-diene terpolymers, polychloroprene, poly(2,3-dimethylbutadiene), poly(butadiene-co-pentadiene), chlorosulfonated polyethylenes, polysulfide elastomers, silicone elastomers, poly(butadiene-co-nitrile), hydrogenated nitrile-butadiene copolymers, acrylic elastomers, ethylene-acrylate copolymers, fluorinated elastomers, fluorochlorinated elastomers, fluorobrominated elastomers and combinations thereof. The elastomeric polymer may be a thermoplastic elastomer. Exemplary useful thermoplastic elastomeric polymer resins include block copolymers, made up of blocks of glassy or crystalline blocks of, for example, polystyrene, poly(vinyltoluene), poly(t-buty lstyrene), and polyester, and elastomeric blocks of, for example, polybutadiene, polyisoprene, ethylene-propy lene copolymers, ethylene-butylene copolymers, polyether ester, and combinations thereof. Some thermoplastic elastomers are commercially available, for example, poly(styrene-butadiene-styrene) block copolymers marketed by Shell Chemical Company, Houston, Texas. under the trade designation “KRATON”.

Other additives may be incorporated into the composite according to the present disclosure depending on the application (e.g., preservatives, curatives, mixing agents, colorants, dispersants, floating or anti-setting agents, flow or processing agents, wetting agents, air separation promoters, functional nanoparticles, and acid/base or water scavengers).

In some embodiments, the composites according to the present disclosure comprise an impact modifier (e.g., an elastomeric resin or elastomeric filler). Exemplary impact modifiers include polybutadiene, butadiene copolymers, polybutene, ground rubber, block copolymers, ethylene terpolymers, core-shell particles, and functionalized elastomers available, for example, from Dow Chemical Company, Midland, MI, under the trade designation “AMPLIFY GR-216”.

In some embodiments, composites disclosed herein may further comprise other density modifying additives like plastic bubbles (e.g., those available under the trade designation “EXPANCEL” from Akzo Nobel, Amsterdam, The Netherlands), blowing agents, or heavy fillers. In some embodiments, composites disclosed herein may further comprise at least one of glass fiber, wollastonite, talc, calcium carbonate, titanium dioxide (including nano-titanium dioxide), carbon black, wood flour, other natural fillers and fibers (e.g., walnut shells, hemp, and corn silks), silica (including nano-silica), and clay (including nano-clay).

In some embodiments, the coated glass bubbles have a d₅₀ particle diameter less than 200 μm, less than 150 μm, less than 100 μm, or even less than 50 μm. In some embodiments, the coated glass bubbles have a d₅₀ particle diameter ranging from 1 μm to 200 μm, 10 μm to 100 μm, 10 μm to 75 μm, or even 10 μm to 40 μm. The glass bubbles with a d₅₀ particle diameter less than 200 microns have utility for many applications, some of which require certain size, shape, density, and/or strength characteristics. For example, glass bubbles are widely used in industry as additives to polymeric compounds where they may serve as modifiers, enhancers, rigidifiers, and/or fillers. Generally, it is desirable that the glass bubbles be strong enough to avoid being crushed or broken during further processing of the polymeric compound, such as by high pressure spraying, kneading, extrusion or injection molding. For many applications, it is also desirable to provide low density glass bubbles, for example, in applications wherein weight is an important factor.

The coated glass bubbles of the present disclosure may be used in any variety of applications where glass bubbles are currently used. However, the silica coating can advantageously reduce the dielectric loss and/or reduce the alkali leaching of soda-lime borosilicate glass bubbles, making the coated glass bubbles of the present disclosure particularly suited for use in printed circuit boards and telecommunications. In some particularly advantageous embodiments, the coated glass bubbles are used as filler for resin composites used to make printed circuit boards in the electronics industry. Exemplary resins include polychlorinated biphenyl, silicone, epoxies; polyphenylene oxides (PPO); polyphenyl ether (PPE); and blends of two or more such resins.

### EXAMPLES

Objects and advantages of this invention are further illustrated by the following examples, but the particular materials and amounts thereof recited in these examples, as well as other conditions and details, should not be construed to unduly limit this invention. These examples are merely for illustrative purposes only and are not meant to be limiting on the scope of the appended claims.

All materials are commercially available, for example, from Sigma-Aldrich Chemical Company, Milwaukee, WI, USA, or known to those skilled in the art, unless otherwise stated or apparent.

The following abbreviations are used in this section: L=liters, mL=milliliters, g=grams, mm=millimeters, min=minutes, h=hours, ppm=parts per million, MΩ=megaOhms, ° C.=degrees Celsius, GHz=gigahertz, RPM=revolutions per minute, cc=cubic centimeters. Abbreviations for materials used in this section, as well as descriptions of the materials, are provided in Table 1.

TABLE 1
Materials used in the Examples

| Abbreviation | Description and Source |
|---|---|
| BUBBLE A | Hollow glass microspheres available under the trade |
| | designation 3M GLASS BUBBLES iM16K from 3M, |
| | St. Paul, MN |
| BUBBLE B | Hollow glass microspheres available under the trade |
| | designation 3M GLASS BUBBLES S4630 from 3M, |
| | St. Paul, MN |
| TEOS | Tetraethyl orthosilicate available from TCI America, |
| | Portland, OR or from FUJIFILM Wako Pure Chemical |
| | Corporation, 053-03476 |
| Ethanol | Ethyl alcohol, available from EMD Millipore Corp., |
| | Darmstadt, Germany |
| Aqueous | Concentrated ammonium hydroxide, available from |
| ammonia | EMD Chemicals Inc, Darmstadt, Germany |
| L(+)-Arginine | L(+)-Arginine, available from FUJIFILM Wako Pure |
| | Chemical Corporation, 017-04612 |
| HCl | Concentrated hydrochloric acid, available from EMD |
| | Chemicals |
| Tetrachlorosilane | SiCl₄, available from Gelest, Morrisville, PA |
| Deionized Water | Water purified with an Auto Still WG 250 purification |
| | system from Yamato Scientific Company, LTD and |
| | having an electrical conductivity less than |
| | 0.5 × 10⁻⁴ S/m. |

### Test Methods

### Method for Density

For EX-1 through EX-3 and CE-1 through CE-4, the density of glass bubbles was measured using helium pycnometry with an ACCUPYC II TEC, available from Micromeritics Instrument Corp., Norcross, GA. The results are presented in Table 3.

For EX-4 and CE-5, the density of glass bubbles was measured using nitrogen pycnometry with an ACCUPYC II 1340, available from Shimadzu Corporation. The results are presented in Table 5.

### Method for Moisture Analysis

Glass bubbles samples were analyzed using a 851 Titrando KF coulometer and an 874 Oven Sample Processor, both available from Metrohm USA, Riverview, FL. About 0.2 g of coated glass bubbles sample was weighed into a vial and sealed. Oven temperature was set at 250° C. The results are presented in Table 3.

### Method for Sodium Leaching

A sample of 1 g of glass bubbles and 50 mL of 18 MΩ water were loaded into a polyethylene bottle. This was placed on a shaker table for 15 min and then loaded into an oven at 80° C. for 1 h. After 1 h, the sample was removed, and placed on a shaker table for 15 min. A 2 mL sample was filtered through a 0.2-micron syringe filter into a separate polyethylene bottle. The elemental composition of extracted ions was measured by ICP-MS. A sample blank was run in parallel with the samples. All efforts were made to eliminate any possibility of incidental contamination; the samples were stored in plastic bottles that were thoroughly cleaned and rinsed with 18 MΩ water. The samples were kept away from dust and particulates by covering them whenever possible. Results are given in units of ppm in Table 3.

### Method for Dielectric Properties I

For CE-1, EX-4 and CE-5, the complex permittivity of samples was measured in a 2.45 GHz dielectric resonator. For the 2.45 GHz resonator measurements, the samples were contained within an 8.460 mm outer diameter, 3.970 mm inner diameter PTFE sleeve centered in the dielectric resonator. A Nicholson-Ross inversion algorithm was used to compute complex permittivity from the measured S-parameters. Measurements were performed with an 8510C Vector Network Analyzer available from Agilent, Santa Clara, CA. The data are shown in Tables 3 and 5.

### Method for Dielectric Properties 2

For EX-1 through EX-3 and CE-2 through CE-4, the dielectric properties ε′ and ε″ of powders were measured using resonant cavity perturbation method described in ASTM D2520-13. Resonant cavity was made of 12 in (30.48 cm) long WR187 waveguide (part # MRHC187HHA12A) from Microtech, Inc., Cheshire, CT and two coupling end plates made of 0.036 inch (0.091 cm) thick aluminum with iris holes diameter 0.395 inch (1.00 cm). For loading samples into cavity, two holes of 0.200 inch (0.508 cm) in diameter were made in the center of WR187 waveguide as exemplified in FIG. 4 of ASTM D2520-13. Manufactured cavity had resonant frequency≈5.42 GHz (TE109 mode) and quality factor Q≈3600.

Coaxial 3.5 mm to WR187 adapters were used to connect cavity to Vector Network Analyzer (VNA) ZNB20 from Rohde & Schwarz. The full 4 port calibration was performed for 3.5 mm connectors using calibration kit ZV-Z53 from Rohde & Schwarz. The VNA was set to operate at −5dBm of RF power, 100 Hz IF bandwidth, 5.41 GHz central frequency and 25 MHz sweep span for 1601 test points. The VNA was set to measure S21-paramter (in dB format) which had a transmission peak at resonant frequency fr with 3dB bandwidth Δf3dB and quality factor defined as Q=fr/Δf3dB.

PTFE tubing with nominal I.D. of 0.166 inch (0.422 cm) and wall thickness of 0.010 inch (0.025 cm) was used to load powder samples into the cavity; the tubes were closed at one end. Tubes were weighed before and after loading with powder and the density was used to calculate the sample volume in the tube also referred to as Vs. The powder was loaded to be at least ˜0.04-0.08 inch (0.10-0.20 cm) above top and bottom wall of the cavity when placed in for measurement. The recorded parameters were resonant frequency fs and quality factor Qs with specimen. To remove response from the Teflon tube, each tube was also measured prior to loading powder under the test, then recorded parameters were treated as of empty cavity with resonant frequency fc and quality factor Qc. The equations for rod geometry from Table 1 of ASTM D2520-13 were used to calculate real permittivity (ε′) and imaginary permittivity (ε″) of the powder samples. The dielectric loss tangent, typically referred to as tan δ, is a frequency dependent parameter of a dielectric material that quantifies its inherent dissipation of electromagnetic energy to heat energy. The term refers to the tangent of the angle in a complex plane between the resistive (lossy) component of an electromagnetic field and its reactive (lossless) component. It is conveniently defined as the ratio of the imaginary permittivity of a material to its real permittivity value, i.e., tan δ=ε″/ε′. Dielectric constant is reported as the value of ε′ and the loss tangent is reported as the ratio ε″/ε′ in Table 3.

### Electrical Conductivity Measurements

Electrical conductivity measurements were used to assess the extent of alkali leaching from glass bubbles in EX-4 and CE-5. Measurements were made using a HORIBA LAQUAtwin EC-33B Compact Conductivity Meter, available from HORIBA Advanced Techno, Co., Ltd.

Test solutions were made by mixing 1 part by weight glass bubbles with 100 parts by weight distilled water in a plastic bottle. The mixture was placed in an oven at 80° C. for 1 hour followed by cooling to room temperature. The mixture was then filtered to remove the glass bubbles. The resultant filtrate was used as the test solution.

The relative value of electrical conductivity (RVEC) was calculated according to the following equation:

$$RVEC = \frac{electrical conductivity of ion leaching solution of coated glass bubbles}{electrical conductivity of ion leaching solution of non - coated glass bubbles}$$

The reduction rate of electrical conductivity (RREC) was calculated according to the following equation: RREC=(1−RVEC)×100%.

Electrical conductivity data are reported in Table 5.

### Aging Treatment

For EX-4 and CE-5, the silica coated glass bubbles were subjected to aging treatment using a Memmert HCP 108 Humidity Chamber (Memmert GmbH+Co. KG, Germany). The coated glass bubbles were placed in the chamber for 120 hours at 40° C. and 90% RH (relative humidity). Aging data are reported in Table 5.

### Comparative Example 1 (CE-1)

For CE-1, BUBBLE A was characterized as received.

### Examples 1-3 (EX-1 Through EX-3) and Comparative Examples 2-4 (CE-2 Through CE-4)

For EX-1through EX-3, 9.0 g of BUBBLE A were charged into a glass frit funnel-type fluidized bed chemical vapor deposition (CVD) reactor with 45 mm inner diameter reactor as described, for example, in Example 1 of U.S. Pat. No. 5,673,148 (Morris et al). The reactor was wrapped with electric heating tape and heated to temperatures above ambient for some Examples, as indicated in Table 2. The temperature was monitored using a thermocouple in the fluidized bed. The bed of BUBBLE A was fluidized with a stream of about 1.5 L/min nitrogen gas introduced into the reactor through the glass frit (i.e., from the bottom of the bed). Water was also introduced into the reactor, below the glass frit, in a stream of nitrogen carrier gas bubbled through water in a chamber separate from the reactor, at flow rates indicated in Table 2 (Water Carrier Gas). A second stream of Nitrogen, which was not humidified, was introduced below the frit at flow rates indicated in Table 2 (Additional Nitrogen). In this way, the fluidization gas flow rate could be maintained while the stoichiometry of the CVD precursor materials (i.e., water and tetrachlorosilane) could be varied. A CVD precursor vapor was simultaneously introduced into the reactor, above the glass frit, in a stream of nitrogen carrier gas by bubbling the carrier gas through the neat liquid CVD precursor SiCl₄ at the flow rate indicated in Table 2 (SiCl₄ Carrier Gas) in a chamber separate from the reactor. The bottom of the bed was agitated with a PTFE coated magnetic stir bar (100 RPM). After the coating time indicated in Table 2, the nitrogen flow through the CVD precursor and the power to the electric heating tape, if applicable, were turned off. The resulting coated glass bubbles were collected.

EX-1, EX-2, and EX-3 were calcined using the following procedure. Coated glass bubbles were loaded into an alumina crucible and placed in a furnace. The furnace was heated using the following schedule: ramp at 200° C./h to 675° C. and then hold for 1 h. The furnace was then cooled at 200° C./h to 100° C. and then allowed to further cool toward ambient temperature. The calcined samples were removed from the furnace after 16 h.

For CE-2, a sample of EX-1 was collected prior to calcining. For CE-3, a sample of EX-2 was collected prior to calcining. For CE-4, a sample of EX-3 was collected prior to calcining.

TABLE 2
Coating Conditions

| | | | Gas flow rates | | |
|---|---|---|---|---|---|
| | | Temper- | | | Additional |
| | Time | ature | SiCl₄ Carrier | Water Carrier | Nitrogen |
| Example | (min) | (° C.) | Gas (cc/min) | Gas (L/min) | (cc/min) |
| EX-1 | 60 | 50 | 50 | 1 | 500 |
| EX-2 | 37.5 | 75 | 50 | 1 | 500 |
| EX-3 | 15 | ambient | 50 | 1.25 | 250 |

TABLE 3
Characterization

| | | | Moisture | Sodium | Dielectric | Loss |
|---|---|---|---|---|---|---|
| Example or | | Density | Content | Leaching | Constant | Tangent |
| Comparative | Calcined | (g/cc) | (ppm) | (ppm) | (ε′) | (tan δ) |
| CE-1 | No | 0.4597 | 1829 | 62.6 | 1.32 | 0.0021 |
| CE-2 | No | 0.5644 | 15134 | 12.8 | 1.96 | 0.0170 |
| CE-3 | No | 0.4969 | 9700 | 18.1 | 1.80 | 0.0100 |
| CE-4 | No | 0.4798 | 8546 | 16.0 | 1.65 | 0.0106 |
| EX-1 | Yes | 0.5716 | 104 | 3.6 | 1.76 | 0.0026 |
| EX-2 | Yes | 0.506 | 136 | 11.9 | 1.68 | 0.0029 |
| EX-3 | Yes | 0.4908 | 181 | 12.3 | 1.67 | 0.0029 |

*Properties were not measured.

### Example 4 (EX-4)

BUBBLE B, a solution of ethanol/deionized water, and a solution of L(+)-Arginine dissolved in deionized water were added to a glass bottle according to the amounts in Table 4. The mixture was stirred at approximately 25° C. for 30 minutes using a thermostatic bottle stirrer (THERMO UNIT T-368, TAITEC Corporation). Then TEOS was added to the mixture, and the mixture was stirred at 60° C. for 16 hours using the thermostatic bottle stirrer. The coated glass bubbles were then filtered from the solution by suction filtration, and dried at 120° C. for 2 hours.

The coated glass bubbles were calcined at 650° C. using an electric furnace according to the following schedule: temperature ramped up to 650° C. in 1 hour; and held the temperature at 650° C. for an additional hour.

Test results are provided in Table 5.

### Comparative Examples 5

For CE-5, BUBBLE B was characterized as received. The results are provided in Table 5.

TABLE 4
Amounts of Raw Materials Used in EX-4 and CE-5

| | Glass | | Deionized | | | |
|---|---|---|---|---|---|---|
| | Bubbles | EtOH | water | Catalyst | TEOS | Temp |
| Example or Comparative | (pts. wt.*) | (pts. wt.*) | (pts. wt.*) | (pts. wt.*) | (pts. wt.*) | (° C.) |
| EX-4 | 10 | 25.2 | 22.3 | 0.109 | 6.5 | 650 |
| Coated BUBBLE B - 650° C. | | | | L(+)-Arginine | | |
| CE-5 | 10 | — | — | — | — | — |
| Uncoated BUBBLE B | | | | | | |

“pts. wt.” means “parts by weight”.

TABLE 5
Characterization

| | | Electrical | | | | | |
|---|---|---|---|---|---|---|---|
| | | Conductivity of Ion | | | | Dielectric | Loss |
| | | Leaching Solution | | Dielectric | Loss | Constant | Tangent |
| Example or | Density | Relative | Reduction | Constant | Tangent | (ε′) | (tan δ) |
| Comparative | (g/cc) | Value | Rate [%] | (ε′) | (tan δ) | after aging | after aging |
| EX-4 | 0.53 | 0.08 | 92 | 1.83 | 0.0037 | 1.83 | 0.0039 |
| Coated BUBBLE B - | | | | | | | |
| 650° C. | | | | | | | |
| CE-5 | 0.47 | 1 | 0 | 1.81 | 0.0056 | 1.82 | 0.0100 |
| Uncoated BUBBLE B | | | | | | | |

Foreseeable modifications and alterations of this invention will be apparent to those skilled in the art without departing from the scope and spirit of this invention. This invention should not be restricted to the embodiments that are set forth in this application for illustrative purposes. To the extent that there is any conflict or discrepancy between this specification as written and the disclosure in any document mentioned or incorporated by reference herein, this specification as written will prevail.

Thus, the present disclosure provides, among other things: silica coated glass bubbles comprising a glass bubble and a silica coating in direct contact with the outer surface of the bubble, wherein the silica coating is free of silanol groups; composites comprising a polymer and a plurality of the silica coated glass particles dispersed therein; articles comprising the composite; and methods for making the silica coated glass bubbles. Various features and advantages of the present disclosure are set forth in the following claims.

1. A particle comprising:
a glass bubble having an outer surface; and
a silica coating in direct contact with the outer surface,
wherein the silica coating is substantially free of silanol groups, and
wherein the silica coating is not surface modified with hydrophobic groups.

2. The particle of claim 1, wherein the glass bubble comprises a soda-lime borosilicate glass.

3. The particle of claim 2, wherein the glass bubble comprises:
50 to 90 wt % silica;
2 to 20 wt % alkali metal oxide; and
1 to 30 wt % boron oxide,
based on the total weight of the glass bubble.

4.-6. (canceled)

7. The particle of claim 1, wherein the silica coating is amorphous.

8. The particle of claim 1, wherein the coating covers at least 90% of the outer surface of the glass bubble.

9. The particle of claim 1, wherein the silica coating is continuous.

10. The particle of claim 1, wherein the silica coating has a thickness ranging from 50 nm to 250 nm.

11. The particle of claim 1, wherein the dielectric constant (Dₖ) of the particle is no greater than 2.

12. The particle of claim 1, wherein the dielectric loss (tan δ) is no greater than 0.01.

13. A composite comprising:
a polymer; and
a plurality of the particles of claim 1 dispersed within the polymer.

14. The composite of claim 13, wherein the polymer is thermoplastic and selected from the group consisting of polyolefins, fluorinated polyolefins, polyimide, polyamide-imide, polyether-imide, polyetherketone resins, polystyrenes, polystyrene copolymers, polyacrylates, polymethacrylates, polyesters, polyvinylchloride (PVC), liquid crystal polymers (LCP), polyphenylene sulfides (PPS), polysulfones, polyacetals, polycarbonates, polyphenylene oxides (PPO), polyphenyl ether (PPE), and blends thereof.

15. The composite of claim 13, wherein the polymer is a thermoset selected from the group consisting of epoxy, polyester, polyurethane, polyurea, silicone, polysulfide, and phenolic.

16. (canceled)

17. The composite of claim 13, wherein the glass bubbles have a d₅₀ particle diameter ranging from 1 μm to 200 μm.

18. An article comprising the composite of claim 13.

19. The article of claim 18 comprising a printed circuit board.

20. A method of making a plurality of the particles of claim 1, the method comprising:
providing a plurality of the glass bubbles;
depositing a silica coating onto the surface of the glass bubbles by chemical vapor deposition with a silica CVD precursor; and
calcining the coated glass bubbles.

21. The method of claim 20, wherein the calcining temperature ranges from 650° C. to 750° C.

22. The method of claim 20, wherein the silica CVD precursor is tetrachlorosilane, tetrabromosilane, or a combination thereof.

23. A method of making a plurality of the particles of claim 1, the method comprising:
providing a plurality of the glass bubbles;
depositing a silica coating onto the surface of the glass bubbles by solution coating, the silica coating resulting from the hydrolysis of a silica precursor in alcohol in the presence of an ammonia catalyst;
separating the silica coated glass bubbles from the solution; and
calcining the silica coated glass bubbles.

24.-25. (canceled)

26. A method of making a plurality of the particles of claim 1, the method comprising:
providing a plurality of the glass bubbles;
depositing a silica coating onto the surface of the glass bubbles by solution coating, the silica coating resulting from the hydrolysis of a silica precursor in alcohol in the presence of a basic amino acid catalyst;
separating the silica coated glass bubbles from the solution; and
calcining the silica coated glass bubbles.

27.-28. (canceled)
